(19) United States
(12) Patent Application Publication
(10) Pub. No.: US 2025/0093763 A1
(43) Pub. Date: Mar. 20, 2025

(54) PHOTOMASK AND METHOD OF MANUFACTURING INTEGRATED CIRCUIT DEVICE BY USING THE SAME

(71) Applicant: Samsung Electronics Co., Ltd., Suwon-si (KR)

(72) Inventors: Akio Misaka, Suwon-si (KR); Bongkeun Kim, Suwon-si (KR); Ran Lee, Suwon-si (KR); Sanghwa Lee, Suwon-si (KR); Wonjoo Im, Suwon-si (KR)

(21) Appl. No.: 18/818,984

(22) Filed: Aug. 29, 2024

(30) Foreign Application Priority Data
Sep. 19, 2023 (KR) 10-2023-0125008

(51) Int. Cl. G03F 1/24; G03F 7/00

(52) U.S. Cl. CPC G03F 1/24; G03F 7/70033; G03F 7/70091

(57) ABSTRACT

A photomask for a photolithography process includes a mask substrate, a reflective multilayer on the mask substrate, and a light absorber pattern on the reflective multilayer and having hole patterns, wherein the hole patterns include a main hole pattern for pattern transfer onto a wafer, first sub-resolution assist feature (SRAF) hole patterns arranged at regular intervals to provide honeycomb lattices in a first region centered around the main hole pattern and having a first pitch less than or equal to a diffraction limit in the photolithography process, and second SRAF hole patterns arranged at regular intervals to surround the main hole pattern and the first SRAF patterns and providing honeycomb lattices in a second region centered around the main hole pattern and surrounding the first region, the second SRAF hole patterns being arranged with a second pitch less than or equal to the diffraction limit in the photolithography process.

### REFERENCE TO RELATED APPLICATION

This application is based on and claims priority under 35 U.S.C. § 119 to Korean Patent Application No. 10-2023-0125008, filed on Sep. 19, 2023, in the Korean Intellectual Property Office, the disclosure of which is incorporated by reference herein in its entirety.

### BACKGROUND

The inventive concepts relate to a photomask and a method of manufacturing an integrated circuit device by using the photomask, and more particularly, to a photomask for a photolithography process that uses an extreme ultraviolet (EUV) light source and a method of manufacturing an integrated circuit device by using the photomask.

Along with the rapid reduction in linewidths of circuit patterns constituting integrated circuit devices, photolithography techniques using EUV light sources have been used to manufacture integrated circuit devices. In particular, in EUV photolithography techniques, phase-shifting masks (PSMs) may be useful to form hole patterns having small sizes. PSMs that have been developed so far have higher reflectivity, due to a limit in material thereof, than ideal reflectivity required for EUV photolithography processes. Therefore, when PSMs are used in EUV photolithography techniques, issues may occur such as the formation of unintended patterns due to unintended printing caused by side-lobe intensity, or due to unintended background printing caused by the light-exposure of a photoresist film around a targeted hole pattern.

### SUMMARY

The inventive concepts provide a photomask used to form a hole pattern having a relatively small size in a photolithography process that uses an extreme ultraviolet (EUV) light source as an exposure light source, the photomask having a structure capable of solving issues of the formation of an unintended pattern due to unintended printing caused by side-lobe intensity and/or due to unintended background printing caused by the light-exposure of a photoresist film around a targeted hole pattern.

The inventive concepts also provide a method of manufacturing an integrated circuit device, the method being capable of solving issues of the formation of an unintended pattern due to unintended printing caused by side-lobe intensity and/or due to unintended background printing caused by the light-exposure of a photoresist film around a targeted hole pattern, when a phase-shifting mask (PSM) is used to form a hole pattern having a relatively small size in a photolithography process that uses an extreme ultraviolet (EUV) light source as an exposure light source.

According to aspects of the inventive concepts, there is provided a photomask for a photolithography process, the photomask including a mask substrate, a reflective multilayer on the mask substrate, and a light absorber pattern arranged on the reflective multilayer and having a plurality of hole patterns, wherein the plurality of hole patterns include a main hole pattern for transferring a pattern onto a wafer, a plurality of first sub-resolution assist feature (SRAF) hole patterns arranged at regular intervals to provide a plurality of first honeycomb lattices in a first region, wherein the first region is centered around the main hole pattern, and wherein the plurality of first SRAF hole patterns are arranged with a first pitch that is less than or equal to a diffraction limit in the photolithography process, and a plurality of second SRAF hole patterns arranged at regular intervals to provide a plurality of second honeycomb lattices in a second region, wherein the plurality of second SRAF hole patterns surround the main hole pattern and the plurality of first SRAF hole patterns, wherein the second region is centered around the main hole pattern and surrounds the first region, and wherein the plurality of second SRAF hole patterns are arranged with a second pitch that is less than or equal to the diffraction limit in the photolithography process.

According to aspects of the inventive concepts, there is provided a photomask for a photolithography process that uses an extreme ultraviolet (EUV) light source, the photomask including a mask substrate, a reflective multilayer on the mask substrate, and a light absorber pattern arranged on the reflective multilayer and having a plurality of hole patterns, wherein the plurality of hole patterns include a plurality of main hole patterns for transferring a pattern onto a wafer, a plurality of first sub-resolution assist feature (SRAF) hole patterns including a plurality of first local groups and a plurality of second local groups, wherein the plurality of second local groups are respectively arranged between ones of the plurality of first local groups, wherein a first subset of the plurality of first SRAF hole patterns are included in each of the plurality of first local groups and are arranged at regular intervals to provide a plurality of first honeycomb lattices in a first region, wherein the first region is centered around one of the plurality of main hole patterns, wherein a second subset of the plurality of first SRAF hole patterns are included in each of the plurality of second local groups and are linearly arranged along a straight line extending in a radial direction away from the one of the plurality of main hole patterns, and wherein at least the first subset of the plurality of first SRAF hole patterns are arranged with a first pitch that is less than or equal to a diffraction limit in the photolithography process, and a plurality of second SRAF hole patterns arranged at regular intervals to provide a plurality of second honeycomb lattices in a second region, wherein the plurality of second SRAF hole patterns surround the plurality of main hole patterns and the plurality of first SRAF hole patterns, wherein the second region is centered around the one of the plurality of main hole patterns and surrounds the first region, and wherein the plurality of second SRAF hole patterns are arranged with a second pitch that is less than or equal to the diffraction limit in the photolithography process.

According to aspects of the inventive concepts, there is provided a method of manufacturing an integrated circuit device, the method including forming a photoresist film on a substrate, and performing a photolithography process by exposing the photoresist film to light using a photomask, wherein the photomask includes a mask substrate, a reflective multilayer on the mask substrate, and a light absorber pattern arranged on the reflective multilayer and having a plurality of hole patterns, wherein the plurality of hole patterns include a plurality of main hole patterns for transferring a pattern onto a wafer, a plurality of first sub-resolution assist feature (SRAF) hole patterns including a plurality of first local groups and a plurality of second local groups, wherein the plurality of second local groups are respectively arranged between ones of the plurality of first local groups, wherein a first subset of the plurality of first SRAF hole patterns are included in each of the plurality of first local groups and are arranged at regular intervals to provide a plurality of first honeycomb lattices in a first region, wherein the first region is centered around one of the plurality of main hole patterns, wherein a second subset of the plurality of first SRAF hole patterns are included in each of the plurality of second local groups and are linearly arranged along a straight line extending in a radial direction away from the one of the plurality of main hole patterns, and wherein at least the first subset of the plurality of first SRAF hole patterns are arranged with a first pitch that is less than or equal to a diffraction limit in the photolithography process, and a plurality of second SRAF hole patterns arranged at regular intervals to provide a plurality of second honeycomb lattices in a second region, wherein the plurality of second SRAF hole patterns surround the plurality of main hole patterns and the plurality of first SRAF hole patterns, wherein the second region is centered around the one of the plurality of main hole patterns and surrounds the first region, and wherein the plurality of second SRAF hole patterns are arranged with a second pitch that is less than or equal to the diffraction limit in the photolithography process.

### BRIEF DESCRIPTION OF THE DRAWINGS

Embodiments will be more clearly understood from the following detailed description taken in conjunction with the accompanying drawings in which:

FIG. 1 is a cross-sectional view illustrating a schematic structure of a photomask according to some embodiments;

FIG. 2A is a plan view of a portion of a photomask according to some embodiments;

FIG. 2B is an enlarged plan view of the portion of the photomask shown in FIG. 2A;

FIG. 3 is a plan view of a portion of a photomask according to some embodiments;

FIG. 4 is a flowchart illustrating a method of manufacturing an integrated circuit device, according to some embodiments;

FIG. 5A is a plan view of an evaluation photomask for identifying the effect of a photomask, according to some embodiments;

FIG. 5B is a diagram illustrating an illuminator used in an exposure process to identify the effect of a photomask, according to some embodiments;

FIGS. 5C and 5D are graphs each illustrating an aerial simulation result obtained as a result of performing an exposure process by using the evaluation photomask shown in FIG. 5A;

FIGS. 6A and 6B are intensity profiles obtained after performing exposure processes by using the evaluation photomask shown in FIG. 5A under different conditions, respectively;

FIG. 7A is a plan view of another evaluation photomask for identifying the effect of a photomask, according to some embodiments;

FIGS. 7B, 7C, and 7D are graphs illustrating results of performing exposure processes under various conditions by using the evaluation photomask shown in FIG. 7A, respectively;

FIGS. 8A, 8B, and 8C are plan views respectively illustrating a sequence of processes of designing a plurality of hole pattern layouts for manufacturing a photomask according to some embodiments;

FIG. 9A is an aerial image generated by an exposure process that uses a photomask according to some embodiments; and

FIG. 9B is an intensity profile of the aerial image of FIG. 9A.

### DETAILED DESCRIPTION

Hereinafter, example embodiments of the inventive concepts will be described in detail with reference to the accompanying drawings. Like components are denoted by like reference numerals throughout the specification, and repeated descriptions thereof are omitted.

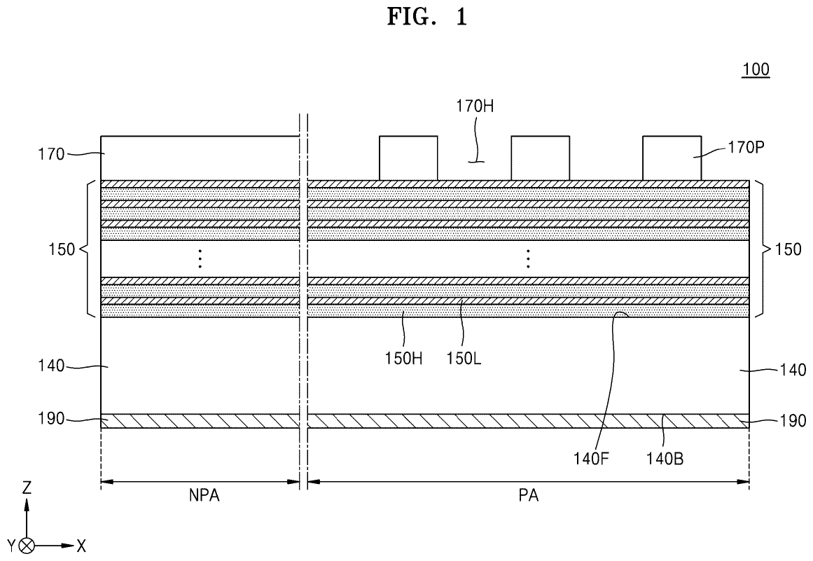

FIG. 1 is a cross-sectional view illustrating a schematic structure of a photomask according to some embodiments.

Referring to FIG. 1, a photomask 100 may correspond to a reflective photomask, which may be used for a photolithography process for manufacturing an integrated circuit device by transferring a pattern onto a wafer through an exposure process that uses an extreme ultraviolet (EUV) wavelength range, for example, an exposure wavelength of about 13.5 nm.

The photomask 100 may include a pattern area PA for transferring a main pattern, which is required to form a unit device constituting an integrated circuit in a chip region of a wafer, and a non-pattern area NPA surrounding the pattern area PA. It will be understood that “an element A surrounds an element B” (or similar language) as used herein means that the element A is at least partially around the element B but does not necessarily mean that the element A completely encloses the element B.

In the pattern area PA, a main pattern constituting the integrated circuit, which is intended to be implemented on the wafer, or an auxiliary pattern, which is necessary during the manufacturing process of the integrated circuit but does not remain in the final product of the integrated circuit, may be formed. For example, the auxiliary pattern may be an auxiliary pattern for transferring an align key pattern onto a scribe lane region of the wafer. The non-pattern area NPA may be a region not including a pattern element for transferring a pattern onto the wafer.

The photomask 100 includes a photomask substrate 140. The photomask substrate 140 may include a dielectric, glass, a semiconductor, or a metal material. In some embodiments, the photomask substrate 140 may include a material having a low thermal expansion coefficient. For example, the photomask substrate 140 may have a thermal expansion coefficient of about 0±0.05×10⁻⁷/° C. at 20° C. For example, the photomask substrate 140 may include low thermal expansion material (LTEM) glass, such as synthetic quartz glass, quartz glass, aluminosilicate glass, soda-lime glass, or SiO₂—TiO₂-based glass, glass-ceramics in which a β-quartz solid solution is precipitated, single-crystal silicon, or SiC.

The photomask substrate 140 may have a first surface 140F on the frontside thereof and a second surface 140B on the backside thereof. In the non-pattern area NPA of the photomask 100, a reflective multilayer 150 for reflecting exposure light, for example, EUV light, and a light absorber layer 170 may be arranged in the stated order on the first surface 140F of the photomask substrate 140. In the pattern area PA of the photomask 100, the reflective multilayer 150 and a light absorber pattern 170P may be arranged in the stated order on the first surface 140F of the photomask substrate 140. The light absorber pattern 170P in the pattern area PA and the light absorber layer 170 in the non-pattern area NPA may include the same material. A backside conductive film 190 may be arranged on the second surface 140B of the photomask substrate 140. In the light absorber pattern 170P in the pattern area PA, a plurality of hole patterns 170H may be formed through the light absorber pattern 170P. That is, the light absorber pattern 170P may have a plurality of hole patterns 170H.

The reflective multilayer 150 may have a multilayered mirror structure obtained by alternately stacking a high-refractive index layer 150H and a low-refractive index layer 150L a plurality of times. For example, the reflective multilayer 150 may have a structure in which the high-refractive index layer 150H and the low-refractive index layer 150L are repeatedly formed for about 20 cycles to about 60 cycles. In some embodiments, the reflective multilayer 150 may include an Mo/Si-periodic multilayer, an Mo compound/Si compound-periodic multilayer, an Ru/Si-periodic multilayer, a Be/Mo-periodic multilayer, an Si/Nb-periodic multilayer, an Si/Mo/Ru-periodic multilayer, an Si/Mo/Ru/Mo-periodic multilayer, or an Si/Ru/Mo/Ru-periodic multilayer.

Materials constituting the reflective multilayer 150 and the thicknesses of the respective layers thereof may be appropriately selected depending on a wavelength band of applied EUV light or the EUV light reflectivity required by the reflective multilayer 150. For example, when the reflective multilayer 150 includes an Mo/Si-periodic multilayer, the Mo layer corresponding to the low-refractive index layer 150L and the Si layer corresponding to the high-refractive index layer 150H, in the reflective multilayer 150, may be formed to respectively have thicknesses selected from a range of about 2 nm to about 5 nm.

Each of the light absorber layer 170 and the light absorber pattern 170P may include a material including Ta as a main component. In some embodiments, each of the light absorber layer 170 and the light absorber pattern 170P may include Ta, as a main component, and at least one element selected from Hf, Si, Zr, Ge, B, N, and H. For example, each of the light absorber layer 170 and the light absorber pattern 170P may include TaN, TaHf, TaHfN, TaBSi, TaBSiN, TaB, TaBN, TaSi, TaSIN, TaGe, TaGEN, TaZr, TaZrN, or a combination thereof. In some embodiments, each of the light absorber layer 170 and the light absorber pattern 170P may include a material including Ta in an amount of at least 40 at %. In some embodiments, each of the light absorber layer 170 and the light absorber pattern 170P may further include oxygen (O) in an amount of about 0 at % to about 25 at %.

In some embodiments, a capping layer may be arranged between the reflective multilayer 150 and the light absorber pattern 170P in the pattern area PA and between the reflective multilayer 150 and the light absorber layer 170 in the non-pattern area NPA. The capping layer may prevent the surface of the reflective multilayer 150 from being oxidized or may protect the reflective multilayer 150 such that the reflective multilayer 150 is not damaged while the light absorber layer 170 undergoes dry etching to form pattern elements, which are to be transferred to the wafer, in the pattern area PA during the manufacturing process of the photomask 100. In some embodiments, the capping layer may include, but is not limited to, Ru, an Ru alloy, or an Si film. The capping layer may have a thickness of about 0.5 nm to about 10 nm. In some embodiments, the capping layer may be omitted.

The backside conductive film 190, which covers the second surface 140B of the photomask substrate 140, may be used to secure the photomask 100 to an electrostatic chuck of an exposure apparatus during an exposure process. The backside conductive film 190 may include a Cr-containing material, such as Cr or CrN, or a Ta-containing material, such as TaB. The backside conductive film 190 may have a thickness of about 20 nm to about 80 nm. A first direction X and a second direction Y may intersect each other and may be parallel to the first surface 140F and/or the second surface 140B of the photomask substrate 140. A third direction Z may intersect the first direction X and the second direction Y and may be perpendicular to the first surface 140F and/or the second surface 140B of the photomask substrate 140. For example, the first direction X and the second direction Y may be horizontal directions, and the third direction Z may be a vertical direction.

Pitches of patterns have been decreased along with the reduction in the design rule of semiconductor devices. Therefore, to more accurately transfer a hole pattern onto a wafer, the pattern resolution has been increased by increasing the number of aperture (NA) of the exposure apparatus used for an exposure process. Nevertheless, there has been a limit in forming fine hole patterns, and thus it has been proposed to introduce EUV light as a light source used for an exposure process. As resolution enhancement technology (RET) for implementing fine contact holes having extremely small critical dimensions (CDs), exposure processes using attenuated phase-shift masks have been introduced. In addition, by introducing a photomask to which a sub-resolution assist feature (SRAF) pattern is introduced as one of auxiliary patterns not greater than the resolution around a hole pattern to further secure a process margin when the hole pattern is formed on a wafer, attempts have been made to improve the resolution due to light scattering by an auxiliary pattern. However, according to the level of technology so far, it is difficult to secure a sufficient process margin to form a fine hole pattern that is required or needed by a highly integrated circuit device. In particular, there is a need to develop a photomask having a structure capable of solving issues of the formation of unintended patterns due to unintended printing caused by side-lobe intensity and/or due to unintended background printing caused by the light-exposure of the surface of a photoresist film around a targeted hole pattern, in an exposure process using an attenuated phase-shift mask. As used herein, the term “SRAF” refers to a feature of a pattern configured such that the feature below the resolution is not printed on a wafer because the intensity generated by the feature below the resolution is lower than the intensity threshold of a photoresist film (which is a film to be exposed to light) on the wafer although the feature interacts with incident radiation.

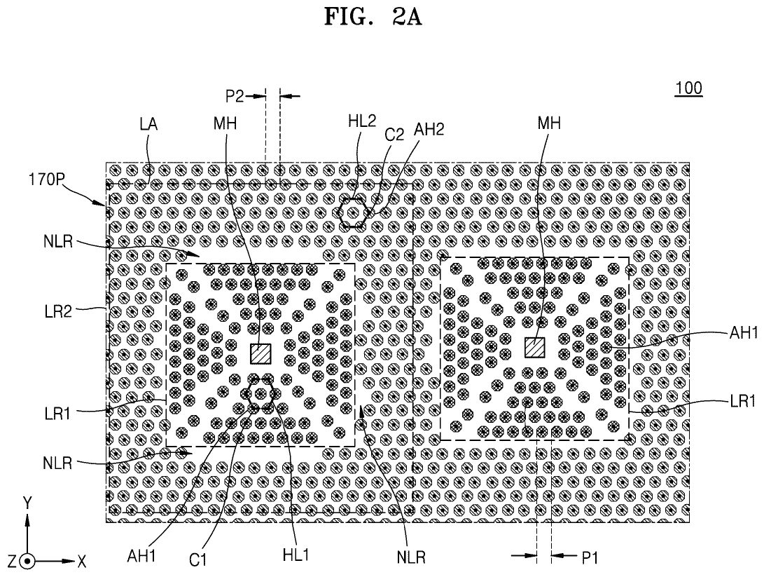

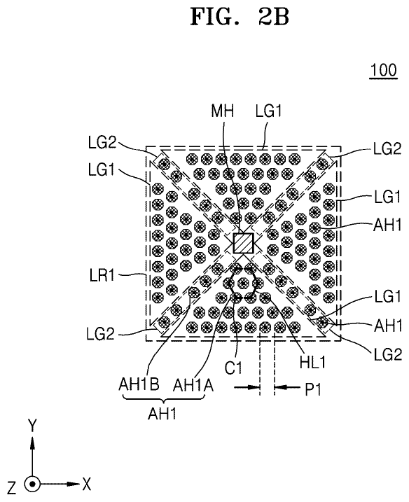

FIG. 2A is a plan view of a portion of the light absorber pattern 170P of the photomask 100, according to some embodiments. FIG. 2B is an enlarged plan view of a first region LR1 of the photomask 100 shown in FIG. 2A.

Referring to FIGS. 2A and 2B, the light absorber pattern 170P of the photomask 100 may include a plurality of main hole patterns MH for transferring patterns onto a wafer, a plurality of first SRAF hole patterns AH1 arranged in a first region LR1, which is defined as a quadrangular region centered around one main hole pattern MH selected from the plurality of main hole patterns MH, and a plurality of second SRAF hole patterns AH2 arranged in a second region LR2 to surround the plurality of main hole patterns MH and the plurality of first SRAF hole patterns AH1, the second region LR2 being centered around the selected one main hole pattern MH and surrounding the first region LR1. The plurality of hole patterns 170H formed in the light absorber pattern 170P shown in FIG. 1 may constitute some of the plurality of first SRAF hole patterns AH1 and the plurality of second SRAF hole patterns AH2.

The plurality of first SRAF hole patterns AH1 may be arranged at regular intervals to form a plurality of honeycomb lattices HL1. The plurality of first SRAF hole patterns AH1 may be arranged with a first pitch P1 that is not greater than (i.e., that is less than or equal to) a diffraction limit in a photolithography process using the photomask 100.

The plurality of second SRAF hole patterns AH2 may be arranged at regular intervals to form a plurality of honeycomb lattices HL2. The plurality of second SRAF hole patterns AH2 may be arranged with a second pitch P2 that is not greater than (i.e., that is less than or equal to) the diffraction limit in the photolithography process using the photomask 100. The first pitch P1 of the plurality of first SRAF hole patterns AH1 may be equal or similar to the second pitch P2 of the plurality of second SRAF hole patterns AH2.

First SRAF hole patterns AH1 constituting at least some groups, from among the plurality of first SRAF hole patterns AH1, may be respectively arranged one-by-one at the positions of the vertices of each of a plurality of hexagonal lattices, which regularly overlap each other to respectively form the plurality of honeycomb lattices HL1. Here, a center C1 of one first SRAF hole pattern AH1 may be aligned to correspond to the vertex of each of the plurality of honeycomb lattices HL1. For example, the first SRAF hole patterns AH1 may be respectively arranged one-by-one at positions of vertices of the plurality of honeycomb lattices HL1. Each of the plurality of honeycomb lattices HL1 may have a hexagonal shape (e.g., in a plan view), and the vertices of the plurality of honeycomb lattices HL1 may correspond to vertices of the hexagonal shape. Ones of the plurality of honeycomb lattices HL1 may regularly overlap each other (e.g., in the third direction Z).

The plurality of second SRAF hole patterns AH2 may be respectively arranged one-by-one at the positions of the vertices of each of a plurality of hexagonal lattices, which regularly overlap each other to respectively form the plurality of honeycomb lattices HL2. Here, a center C2 of one second SRAF hole pattern AH2 may be aligned to correspond to the vertex of each of the plurality of honeycomb lattices HL2. For example, the second SRAF hole patterns AH2 may be respectively arranged one-by-one at positions of vertices of the plurality of honeycomb lattices HL2. Each of the plurality of honeycomb lattices HL2 may have a hexagonal shape (e.g., in a plan view), and the vertices of the plurality of honeycomb lattices HL2 may correspond to vertices of the hexagonal shape. Ones of the plurality of honeycomb lattices HL2 may regularly overlap each other (e.g., in the third direction Z). It will be understood that “an element A overlaps an element B” (or similar language) as used herein means that at least one line intersecting both the elements A and B exists.

The plurality of first SRAF hole patterns AH1 and the plurality of second SRAF hole patterns AH2 may each be arranged on both sides of a straight line passing or extending through the main hole pattern MH to be symmetric with respect to the straight line. In a local region centered around one main hole pattern MH, for example, the local region LA of FIG. 2A, the number of second SRAF hole patterns AH2 may be greater than the number of first SRAF hole patterns AH1.

As shown in FIG. 2B, the plurality of first SRAF hole patterns AH1 may include a plurality of first local groups LG1, which each include a plurality of first SRAF hole patterns AH1A arranged to form honeycomb lattices HL1, and a plurality of second local groups LG2, which each include a plurality of first SRAF hole patterns AH1B arranged in a line along a straight line extending in a radial direction from the main hole pattern MH or in a direction from the main hole pattern MH toward the vertex of the quadrangular region defining the first region LR1, each of the plurality of second local groups LG2 being between two adjacent first local groups LG1 from among the plurality of first local groups LG1. The plurality of first SRAF hole patterns AH1A, which are included in each of the plurality of first local groups LG1, from among the plurality of first SRAF hole patterns AH1 may be arranged in a triangular region between one main hole pattern MH and one side of the quadrangular region defining the first region LR1. As used herein, the plurality of first SRAF hole patterns AH1A may also be referred to as a first subset AH1A of the plurality of first SRAF hole patterns AH1, and the plurality of first SRAF hole patterns AH1B may also be referred to as a second subset AH1B of the plurality of first SRAF hole patterns AH1.

As shown in FIG. 2A, the light absorber pattern 170P of the photomask 100 may include a plurality of non-pattern regions NLR between a region, in which the plurality of first SRAF hole patterns AH1 are concentrated in the first region LR1, and a region, in which the plurality of second SRAF hole patterns AH2 are concentrated in the second region LR2, each of the plurality of non-pattern regions NLR having a width that is greater than each of the first pitch P1 and the second pitch P2.

In the light absorber pattern 170P of the photomask 100, a first radius, r1, of each of the plurality of first SRAF hole patterns AH1A, which are included in each of the plurality of first local groups LG1 in the first region LR1, may be determined according to Inequality 1.

$$P 1 > r 1 > \sqrt{\frac{1.5 \cdot \sqrt{3} \cdot {( P 1 )}^{2} \cdot ( \sqrt{0.03} + \sqrt{RF} )}{3 \cdot π \cdot ( 1 + \sqrt{RF} )}} \qquad [ Inequality 1 ]$$

In Inequality 1, P1 is a first pitch of the plurality of first SRAF hole patterns AH1, and RF is reflectivity in the light absorber pattern 170P of the photomask 100.

The first pitch P1 of the plurality of first SRAF hole patterns AH1 may be defined by Equation 1-1.

$$P 1 = \frac{N A}{λ \cdot ( 1 + σ )} \qquad [ Equation 1 - 1 ]$$

In Equation 1-1, NA is a numerical aperture of a lens used in a photolithography process using the photomask 100, λ is a wavelength of a light source used in the photolithography process, and σ is a radial-direction outer size of an illuminator used in the photolithography process.

In some embodiments, σ may be an integer selected from a range of 0.5 to 0.9. In some embodiments, σ may be determined by the resolution of a photoresist in the photolithography process or by other processes.

When the first pitch P1 of the plurality of first SRAF hole patterns AH1 is defined by Equation 1-1, the first radius, r1, of each of the plurality of first SRAF hole patterns AH1 may be determined according to Inequality 1-2.

$$\frac{N A}{λ \cdot ( 1 + σ )} > r 1 > \sqrt{\frac{1.5 \cdot \sqrt{3} \cdot {( P 1 )}^{2} \cdot ( \sqrt{0.03} + \sqrt{R F} )}{3 \cdot π \cdot ( 1 + \sqrt{R F} )}} \qquad [ Inequality 1 - 2 ]$$

In some embodiments, the first radius, r1, of each of the plurality of first SRAF hole patterns AH1 may be determined according to Equation 1-3.

$$r 1 = \sqrt{\frac{A 1}{π}} \qquad [ Equation 1 - 3 ]$$

In Equation 1-3, A1 is a cross-sectional area of the first SRAF hole pattern AH1.

In the light absorber pattern 170P of the photomask 100, a second radius, r2, of each of the plurality of second SRAF hole patterns AH2 in the second region LR2 may be determined according to Inequality 2.

$$P 2 > r 2 > \sqrt{\frac{1.5 \cdot \sqrt{3} \cdot {( P 2 )}^{2} \cdot ( \sqrt{0.03} + \sqrt{R F} )}{3 \cdot π \cdot ( 1 + \sqrt{R F} )}} \qquad [ Inequality 2 ]$$

In Inequality 2, P2 is a second pitch of the plurality of second SRAF hole patterns AH2, and RF is reflectivity in the light absorber pattern 170P of the photomask 100.

The second pitch P2 of the plurality of second SRAF hole patterns AH2 may be defined by Equation 2-1.

$$P 2 = \frac{N A}{λ \cdot ( 1 + σ )} \qquad [ Equation 2 - 1 ]$$

In Equation 2-1, NA is a numerical aperture of a lens used in a photolithography process using the photomask 100, λ is a wavelength of a light source used in the photolithography process, and σ is a radial-direction outer size of an illuminator used in the photolithography process. A more detailed description of σ is the same as made above.

In some embodiments, the second radius, r2, of each of the plurality of second SRAF hole patterns AH2 may be determined according to Inequality 2-2.

$$\frac{N A}{λ \cdot ( 1 + σ )} > r 2 > \sqrt{\frac{1.5 \cdot \sqrt{3} \cdot {( P 2 )}^{2} \cdot ( \sqrt{0.03} + \sqrt{R F} )}{3 \cdot π \cdot ( 1 + \sqrt{R F} )}} \qquad [ Inequality 2 - 2 ]$$

In Inequality 2-2, NA, λ, and σ are the same as defined above.

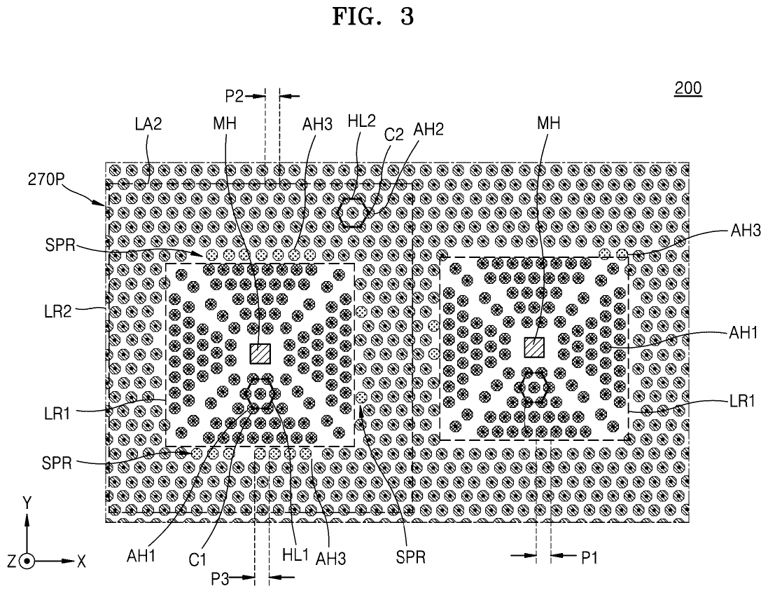

FIG. 3 is a plan view of a portion of a light absorber pattern 270P of a photomask 200 according to some embodiments. In FIG. 3, the same reference numerals as in FIGS. 2A and 2B respectively denote the same members, and repeated descriptions thereof are omitted.

Referring to FIG. 3, the photomask 200 has substantially the same configuration as the photomask 100 described with reference to FIGS. 1, 2A, and 2B. However, the photomask 200 includes a light absorber pattern 270P instead of the light absorber pattern 170P, in the pattern area PA (see FIG. 1). The light absorber pattern 270P has substantially the same configuration as the light absorber pattern 170P described with reference to FIGS. 1, 2A, and 2B. However, the light absorber pattern 270P further includes a plurality of third SRAF hole patterns AH3 between the plurality of first SRAF hole patterns AH1 and the plurality of second SRAF hole patterns AH2.

The plurality of third SRAF hole patterns AH3 may be linearly arranged along a straight line in each of a plurality of separation spaces SPR between the plurality of first SRAF hole patterns AH1 and the plurality of second SRAF hole patterns AH2. The plurality of third SRAF hole patterns AH3 may be arranged with a third pitch P3 that is not greater than (i.e., that is less than or equal to) a diffraction limit in a photolithography process using the photomask 200. The third pitch P3 of the plurality of third SRAF hole patterns AH3 may be equal or similar to at least one of the first pitch P1 of the plurality of first SRAF hole patterns AH1 or the second pitch P2 of the plurality of second SRAF hole patterns AH2.

In a local region centered around the main hole pattern MH, for example, the local region LA2 in FIG. 3, the number of third SRAF hole patterns AH3 may be less than each of the number of first SRAF hole patterns AH1 and the number of second SRAF hole patterns AH2.

In the light absorber pattern 270P of the photomask 200, a third radius, r3, of each of the plurality of third SRAF hole patterns AH3 may be determined according to Inequality 3.

$$\sqrt{\frac{1.5 \cdot \sqrt{3} \cdot {( P 3 )}^{2} \cdot \sqrt{R F} )}{3 \cdot π \cdot ( 1 + \sqrt{R F} )}} \geq r 3 \qquad [ Inequality 3 ]$$

In Inequality 3, P3 is a third pitch of the plurality of third SRAF hole patterns AH3, and RF is reflectivity in the light absorber pattern 270P of the photomask 200.

In the photomask 100 shown in FIGS. 2A and 2B and the photomask 200 shown in FIG. 3, the plurality of first SRAF hole patterns AH1 and the plurality of second SRAF hole patterns AH2 may function as an anti-reflection pattern and thus prevent the printing of an unintended pattern, which may be generated by high reflection.

The plurality of first SRAF hole patterns AH1 may not allow light incident on the photomask 100 to be diffracted even after reflected by the photomask 100. Herein, the plurality of first SRAF hole patterns AH1 may be referred to as non-diffraction SRAFs. The plurality of second SRAF hole patterns AH2 may prevent unintended background printing in the background, which corresponds to a region around a main pattern transferred from the main hole pattern MH onto a wafer. Herein, the plurality of second SRAF hole patterns AH2 may be referred to as background anti-reflection patterns (BARPs).

In the photomasks 100 and 200 according to the inventive concepts, because each of the light absorber patterns 170P and 270P includes the main hole pattern MH, which is for transferring patterns onto a wafer, and the plurality of first SRAF hole patterns AH1 and the plurality of second SRAF hole patterns AH2, which are arranged around the main hole pattern MH with the main hole pattern MH as the center thereof, even when a hole pattern having a relatively small size is formed on a wafer in a photolithography process using EUV light as an exposure light source, unintended printing due to side-lobe intensity may be prevented, and issues of the formation of an unintended pattern due to unintended background printing caused by the light-exposure of the surface of a photoresist film around the hole pattern, which is formed in a photoresist pattern on the wafer by the transfer of the main hole pattern MH, may be solved. In addition, in the photomask 200 shown in FIG. 3, the plurality of third SRAF hole patterns AH3 may be arranged between the plurality of first SRAF hole patterns AH1 and the plurality of second SRAF hole patterns AH2 and thus further enhance the function of preventing unintended printing due to side-lobe intensity.

In the examples of FIGS. 2A, 2B, and 3, although the planar shape of each of the plurality of first SRAF hole patterns AH1, the plurality of second SRAF hole patterns AH2, and the plurality of third SRAF hole patterns AH3 is shown as being circular, the inventive concepts are not limited thereto. In some embodiments, the planar shape of each of the plurality of first SRAF hole patterns AH1, the plurality of second SRAF hole patterns AH2, and the plurality of third SRAF hole patterns AH3 may have various polygonal shapes, such as a hexagon, an octagon, or a decagon.

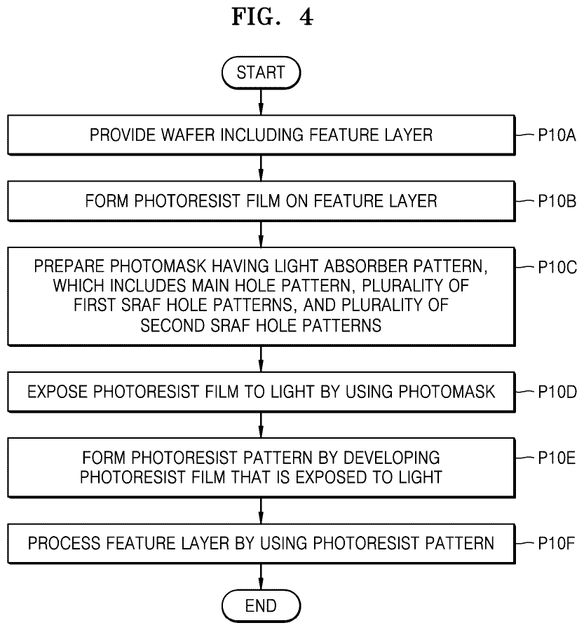

FIG. 4 is a flowchart illustrating a method of manufacturing an integrated circuit device, according to some embodiments.

Referring to FIG. 4, in process P10A, a wafer including a feature layer is provided.

In some embodiments, the feature layer may correspond to a conductive layer or an insulating layer, which is formed on the wafer. For example, the feature layer may include a metal, a semiconductor, or an insulating material. In some embodiments, the feature layer may correspond to the wafer itself.

In process P10B of FIG. 4, a photoresist film is formed on the feature layer.

In some embodiments, the photoresist film may include a resist material for EUV (13.5 nm). In some embodiments, the photoresist film may include a resist for an F2 excimer laser (157 nm), a resist for an ArF excimer laser (193 nm), or a resist for a KrF excimer laser (248 nm). The photoresist film may include a positive photoresist or a negative photoresist.

In process P10C of FIG. 4, a photomask is prepared.

In some embodiments, the photomask may be one photomask selected from the photomask 100 described with reference to FIGS. 1, 2A, and 2B and the photomask 200 described with reference to FIG. 3.

In process P10D of FIG. 4, by using the photomask prepared in process P10C, the photoresist film, which is formed on the feature layer in process P10B, is exposed to light in a reflective exposure system.

In process P10E, a photoresist pattern is formed by developing the photoresist film that is exposed to light.

In process P10F, the feature layer is processed by using the photoresist pattern that is formed in process P10E.

In some embodiments, to process the feature layer according to process P10F, the feature layer may be etched by using the photoresist pattern as an etch mask, thereby forming a fine feature pattern. In some embodiments, to process the feature layer according to process P10F, impurity ions may be implanted into the feature layer by using the photoresist pattern as an ion implantation mask. In some embodiments, to process the feature layer according to process P10F, a separate process film may be formed on the feature layer exposed by the photoresist pattern. The process film may include a conductive film, an insulating film, a semiconductor film, or a combination thereof.

The manufacturing method of an integrated circuit device, which has been described with reference to FIG. 4, includes a process of exposing a photoresist film on a wafer to light by using, as a photomask for an exposure process, the photomask 100 having the light absorber pattern 170P, which includes a plurality of first and second SRAF hole patterns AH1 and AH2, or the photomask 200 having the light absorber pattern 270P, which includes a plurality of first to third SRAF hole patterns AH1, AH2, and AH3. Therefore, in the case where a hole pattern having a relatively small size is formed on a wafer in a photolithography process using EUV light as an exposure light source, even when the photomasks 100 and 200 each have reflectivity that is higher than ideal reflectivity required for an EUV photolithography process, issues of the formation of an unintended pattern, due to unintended printing caused by side-lobe intensity because of high reflectivity, or due to unintended background printing caused by the light-exposure of the surface of a photoresist film around the targeted hole pattern, may be prevented. In addition, according to the manufacturing method of an integrated circuit device, an EUV photolithography process may be performed by using the photomask 100 or 200 according to the inventive concepts, thereby improving a process window when the main hole pattern MH is printed on a wafer.

Next, various evaluation examples for more specifically describing effects of a photomask according to some embodiments are described.

### Evaluation Example 1

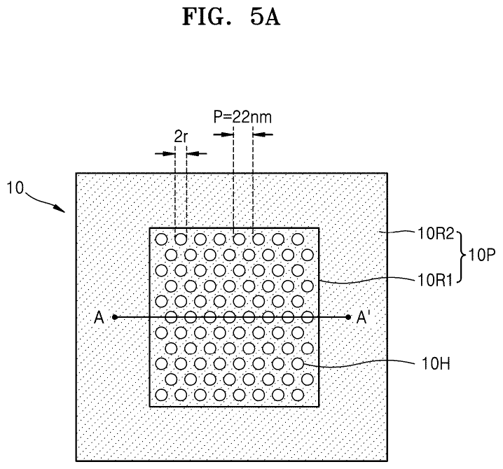

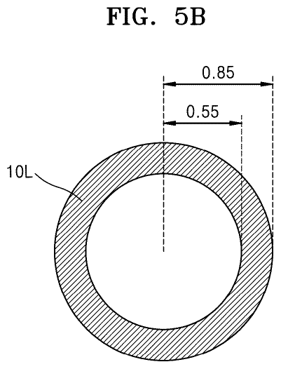

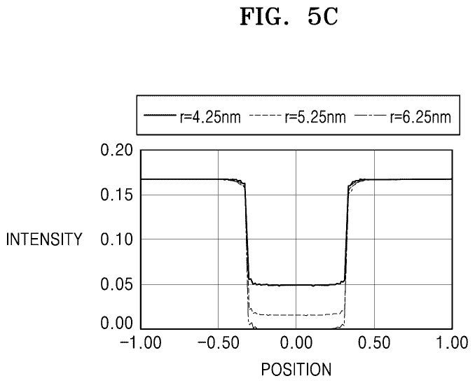

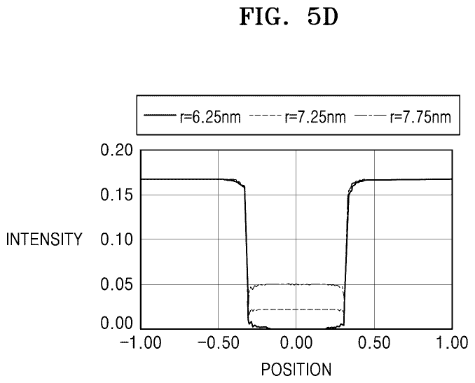

FIG. 5A is a plan view illustrating an evaluation photomask 10 including a PSM and used in the present evaluation example.

Referring to FIG. 5A, the evaluation photomask 10 includes a light absorber pattern 10P including an auxiliary pattern area 10R1, in which a plurality of SRAF hole patterns 10H are symmetrically arranged to form honeycomb lattices, and a non-pattern area 10R2 corresponding to the background and surrounding the auxiliary pattern area 10R1.

FIG. 5B is a diagram illustrating an illuminator 10L used for an exposure process in the present evaluation example. Referring to FIG. 5B, in the present evaluation example, an annular illuminator having σₒᵤₜ/σᵢₙ=0.85/0.55 was used as the illuminator 10L.

FIGS. 5C and 5D are each a graph illustrating an aerial simulation result obtained by performing an exposure process by using the evaluation photomask 10, when the radius, r, of each of the plurality of SRAF hole patterns 10H in the evaluation photomask 10 shown in FIG. 5A has various values. FIGS. 5C and 5D each illustrate an intensity profile in a portion of the evaluation photomask 10 shown in FIG. 5A, taken along a line A-A′.

In the evaluation photomask 10, the reflectivity of the light absorber pattern 10P in a dark field was 17%. In the evaluation photomask 10 shown in FIG. 5A, the pitch P of the plurality of SRAF hole patterns 10H was 22 nm, which is less than a diffraction limit (22.11 nm). Here, the diffraction limit was obtained by assuming σ=0.85 and substituting σ=0.85 into NA/{λ·(1+σ)}. Here, NA is a numerical aperture of a lens used in an exposure process.

From the result of FIG. 5C, it may be seen that the intensity in a central portion of the auxiliary pattern area 10R1 decreases with the increasing radius, r, of the SRAF hole pattern 10H and the intensity is almost close to 0 (zero) when the radius, r, of the SRAF hole pattern 10H is 6.25 nm. On the other hand, from the result of FIG. 5D, it may be seen that the intensity increases with the increasing radius, r, of the SRAF hole pattern 10H when the radius, r, of the SRAF hole pattern 10H is in a range that is greater than 6.25 nm.

Because the pitch P of the plurality of SRAF hole patterns 10H in the evaluation photomask 10 is less than the diffraction limit (22.11 nm), the intensity in the central portion of the auxiliary pattern area 10R1 is generated only by 0-th order diffracted light. From the result of FIG. 5C, it may be seen that, when the auxiliary pattern area 10R1 includes SRAF hole patterns 10H, each having a radius, r, that is less than 6.25 nm, at regular pitches P, the auxiliary pattern area 10R1 makes a 180-degree phase change and thus functions as an attenuator of 0-th order diffracted light, similar to the non-pattern area 10R2. On the other hand, when the auxiliary pattern area 10R1 includes SRAF hole patterns 10H, each having a radius, r, that is greater than 6.25 nm, at regular pitches P, the auxiliary pattern area 10R1 may generate 0-th order diffracted light without a phase change, unlike the non-pattern area 10R2. That is, in the evaluation photomask 10, the auxiliary pattern area 10R1, in which the plurality of SRAF hole patterns 10H are formed, may perform substantially the same function as a pattern having effective reflectivity RE defined by Equation 4.

$$R E = {T}^{2} \qquad [ Equation 4 ]$$

In Equation 4, T is defined by Equation 5.

$$T = \frac{( 1 + \sqrt{R F} ) \cdot π \cdot {( r / 2 )}^{2}}{1.5 \cdot \sqrt{3} \cdot {P}^{2}} - \sqrt{R F} \qquad [ Equation 5 ]$$

In Equation 5, P is a pitch of the plurality of SRAF hole patterns 10H in the evaluation photomask 10, r is a radius of the SRAF hole pattern 10H, and RF is reflectivity in the light absorber pattern 10P of the evaluation photomask 10.

When T in Equation 5 has a negative value, the auxiliary pattern area 10R1 is a phase-shifting pattern with respect to incident light, and when T in Equation 5 has a positive value, the auxiliary pattern area 10R1 is a non-phase-shifting pattern that does not function as a phase-shifting pattern.

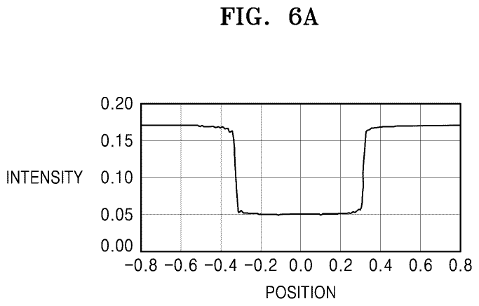

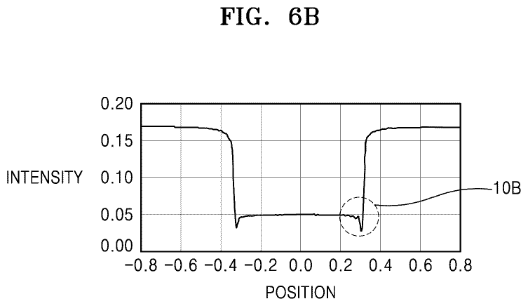

FIG. 6A illustrates an intensity profile obtained from an aerial image when the radius, r, of the SRAF hole pattern 10H in the evaluation photomask 10 shown in FIG. 5A is 4.25 nm (r=4.25 nm), and FIG. 6B illustrates an intensity profile obtained from an aerial image when the radius, r, of the SRAF hole pattern 10H in the evaluation photomask 10 shown in FIG. 5A is 7.75 nm (r=7.75 nm). FIGS. 6A and 6B each illustrate an intensity profile in a portion of the evaluation photomask 10 shown in FIG. 5A, taken along the line A-A′.

In the present evaluation, from the aerial images respectively obtained when r=4.25 nm and when r=7.75 nm, it may be confirmed that the auxiliary pattern area 10R1 has a reflectivity of 5%. However, the evaluation photomask 10 is equivalent to a phase-shifting pattern having a reflectivity of 5% when r=4.25 nm, and the evaluation photomask 10 is equivalent to a non-phase-shifting pattern having a reflectivity of 5% when r=7.75 nm.

In the results of FIGS. 6A and 6B, although a region close to the center of the auxiliary pattern area 10R1 exhibits approximately constant intensity, a boundary region, such as a region 10B of FIG. 6B, between the auxiliary pattern area 10R1 and the non-pattern area 10R2, which corresponds to the background of the auxiliary pattern area 10R1, exhibits intensity that is significantly different from the intensity in the region close to the center of the auxiliary pattern area 10R1. This is because there is a phase boundary effect in the boundary region between the auxiliary pattern area 10R1 and the non-pattern area 10R2, and a dark portion is generated in the region 10B of FIG. 6B, in which there is a phase boundary effect.

According to the inventive concepts, to prevent unintended printing due to side-lobe intensity, the phase boundary effect described above is used. In this regard, the conditions defined in Inequalities 1 and 2 described above mean that the plurality of first SRAF hole patterns AH1A and the plurality of second SRAF hole patterns AH2 in the light absorber pattern 170P of the photomask 100, which has been described with reference to FIGS. 1, 2A, and 2B, are each equivalent to a non-phase-shifting pattern having reflectivity that is greater than 3%, when the reflectivity in the light absorber pattern 170P of the photomask 100 is RF. That is, the minimum intensity obtained from a photomask according to the inventive concepts may be about 3%.

### Evaluation Example 2

To confirm that a non-phase-shifting pattern is useful to prevent side-lobe printing, the following evaluation was performed in the present evaluation example.

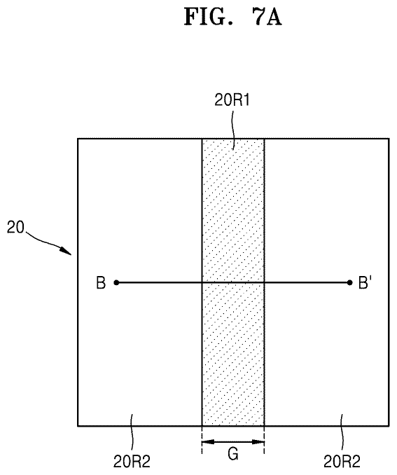

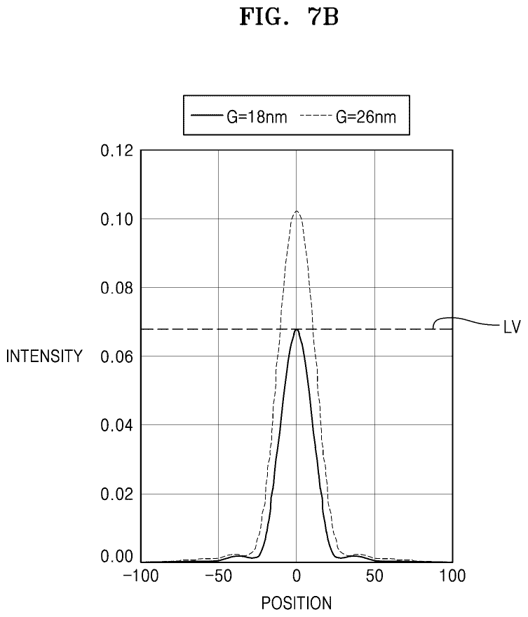

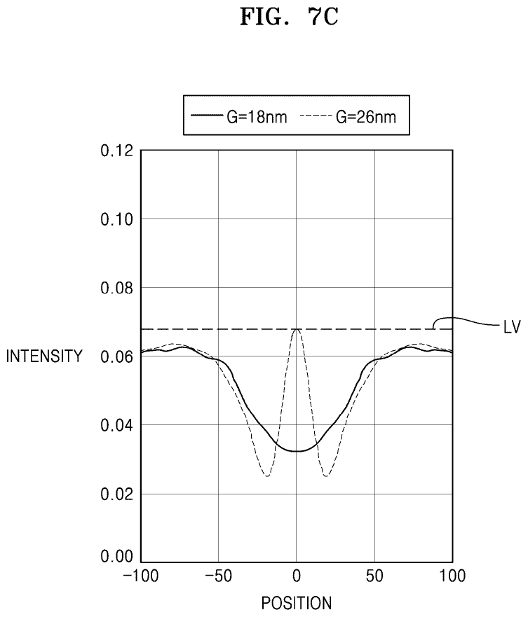

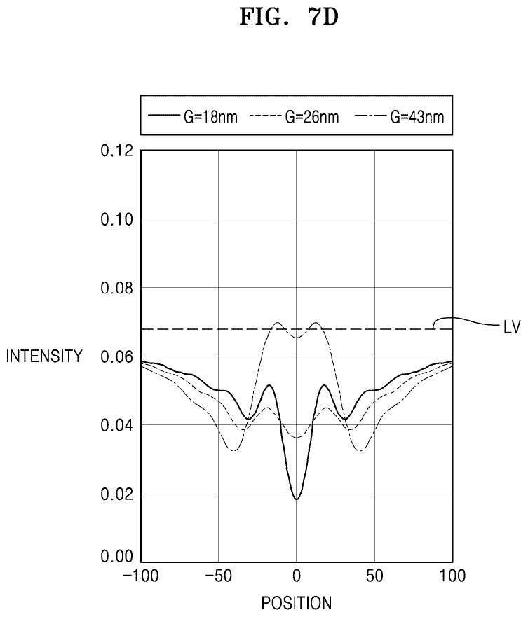

FIG. 7A is a plan view illustrating an evaluation photomask 20 including a PSM and used in the present evaluation example. Referring to FIG. 7A, the evaluation photomask 20 includes a phase-shifting portion 20R1, which has a reflectivity of 17%, and non-phase-shifting portions 20R2 arranged on both sides of the phase-shifting portion 20R1 with the phase-shifting portion 20R1 therebetween.

FIGS. 7B, 7C, and 7D are graphs respectively illustrating results of performing exposure processes under various conditions by using the evaluation photomask 20 shown in FIG. 7A. For the simulations of FIGS. 7B and 7C, an annular illuminator having σₒᵤₜ/σᵢₙ=0.85/0.55 was used as an illuminator. For the simulation of FIG. 7D, an off-axis illumination method, which uses an annular illuminator having σₒᵤₜ/σᵢₙ=0.95/0.75 as an illuminator, was used. That is, in the simulation of FIG. 7D, an off-axis illumination method, in which an off-axis incidence position is farther from the center of the annular illuminator than that of the simulation of FIG. 7C, was applied. FIGS. 7B, 7C, and 7D each illustrate an intensity profile in a portion of the evaluation photomask 20 shown in FIG. 7A, taken along a line B-B′ of FIG. 7A. The dashed line LV in FIGS. 7B, 7C, and 7D indicates a threshold of intensity, at which side-lobe printing occurs, that is, a level of intensity of 7%.

More specifically, FIG. 7B illustrates simulation results when widths G of the phase-shifting portion 20R1 are 18 nm and 26 nm, respectively. From the simulation results of FIG. 7B, it may be confirmed that the reflectivity in the non-phase-shifting portions 20R2 is 0% (that is, RE=0%). The reflectivity in the non-phase-shifting portions 20R2 being 0% means that the non-phase-shifting portions 20R2 are equivalent to a complete anti-reflection pattern, that is, a complete light absorber pattern. In the present evaluation example, it was assumed that side-lobe printing occurs when the intensity is greater than 7%.

From the simulation results of FIG. 7B, it may be seen that, even when all patterns of a PSM include only complete anti-reflection patterns, side-lobe printing may occur in the phase-shifting portion 20R1 in the case where the width G of the phase-shifting portion 20R1 is greater than 18 nm.

FIG. 7C illustrates a simulation result when the reflectivity in the non-phase-shifting portions 20R2 of the evaluation photomask 20 is 6% (that is, RE=6%). From the simulation result of FIG. 7C, it may be seen that, when the width G of the phase-shifting portion 20R1 is less than 26 nm in a PSM including the non-phase-shifting portions 20R2 having a reflectivity of 6%, side-lobe printing does not occur.

In the case where it is intended to prevent side-lobe printing by using a pattern having a reflectivity of 0%, when a plurality of hole patterns are formed in a light absorber layer, it is necessary for each interval between the plurality of hole patterns to be less than 18 nm. On the other hand, when a non-phase-shifting pattern having a reflectivity of 6% is used, to prevent side-lobe printing, each interval between a plurality of hole patterns formed in a light absorber layer may be increased to a range of about 18 nm to about 26 nm.

FIG. 7D illustrates a simulation result when the reflectivity in the non-phase-shifting portions 20R2 of the evaluation photomask 20 is 6% (that is, RE=6%). According to the simulation result of FIG. 7D, in the case where an annular illuminator having σₒᵤₜ/σᵢₙ=0.95/0.75 is used as an illuminator, as confirmed from the simulation result of FIG. 7D, the effects according to the inventive concepts may be maximized as an off-axis incidence position gets farther from the center of the annular illuminator when an off-axis illumination method using the annular illuminator is used. Thus, it may be seen that, when the off-axis incidence position is farther from the center of the annular illuminator, each interval between a plurality of hole patterns formed in a light absorber layer to prevent side-lobe printing, upon using a non-phase-shifting pattern having a reflectivity of 6%, may be further increased to a range of 26 nm to 43 nm.

From the results of Evaluation Example 2, it may be seen that a non-diffraction SRAF and a BARP, which each include a plurality of hole patterns arranged with a pitch that is not greater than a diffraction limit in a photolithography process, each have good effects in preventing side-lobe printing. That is, even when there is an interval that is greater than the diffraction limit and located between the non-diffraction SRAF and the BARP, side-lobe printing may be effectively prevented.

As described with reference to FIGS. 1 to 3, each of the photomasks 100 and 200 according to the inventive concepts includes the light absorber pattern 170P or 270P, which includes the plurality of main hole patterns MH, the plurality of first SRAF hole patterns AH1 surrounding each of the plurality of main hole patterns MH, and the plurality of second SRAF hole patterns AH2 surrounding the plurality of main hole patterns MH and the plurality of first SRAF hole patterns AH1. At least some of the plurality of first SRAF hole patterns AH1 and at least some of the plurality of second SRAF hole patterns AH2 are respectively arranged at regular intervals to form a plurality of honeycomb lattices and respectively have pitches that are not greater than a diffraction limit in a photolithography process. The first radius, r1, of each of the plurality of first SRAF hole patterns AH1 may be determined according to Inequality 1 described above, and the second radius, r2, of each of the plurality of second SRAF hole patterns AH2 may be determined according to Inequality 2 described above.

In the case where an EUV photolithography process is performed by using each of the photomasks 100 and 200 according to the inventive concepts, even when a hole pattern having a relatively small size is formed on a wafer, unintended printing due to side-lobe intensity may be prevented, and issues of the formation of an unintended pattern due to unintended background printing caused by the light-exposure of the surface of a photoresist film around the hole pattern, which is formed in a photoresist pattern on the wafer by the transfer of the main hole pattern MH, may be solved.

In addition, in the case where an EUV photolithography process is performed by using each of the photomasks 100 and 200 according to the inventive concepts, in particular, as confirmed from the simulation result of FIG. 7D, the effects according to the inventive concepts may be maximized as an off-axis incidence position is farther from the center of the annular illuminator when an off-axis illumination method using the annular illuminator is used.

By performing an EUV photolithography process by using each of the photomasks 100 and 200 according to the inventive concepts, when the main hole pattern MH is printed on a wafer, a process window may improve and unintended side-lobe printing around the main hole pattern MH may be prevented.

To manufacture each of the photomasks 100 and 200 according to the inventive concepts, a plurality of first hole pattern layouts corresponding to the plurality of first SRAF hole patterns AH1 may be designed first to be symmetrically arranged in a plurality of quadrangular layout regions, which are each centered around each of a plurality of hole pattern layouts corresponding to the plurality of main hole patterns MH shown in FIGS. 1 to 3, and then, a plurality of second hole pattern layouts corresponding to the plurality of second SRAF hole patterns AH2 may be designed in a region surrounding the plurality of quadrangular layout regions. Next, a plurality of third hole pattern layouts corresponding to the plurality of third SRAF hole patterns AH3 shown in FIG. 3 may be designed, as needed.

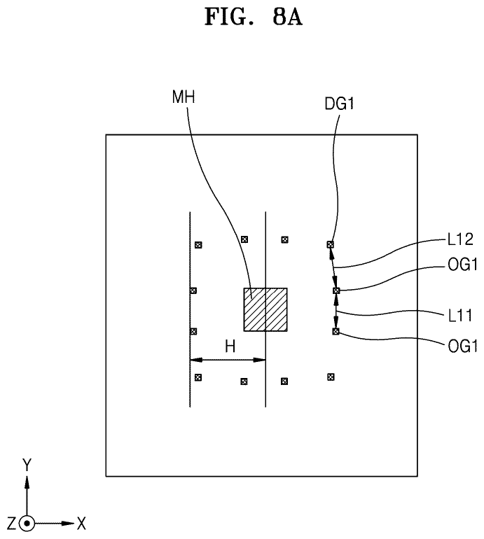

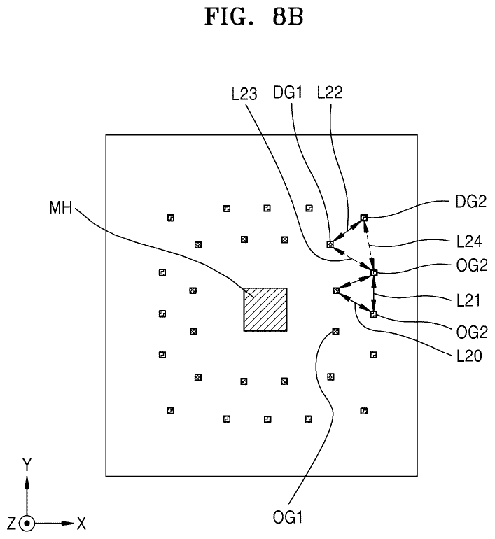

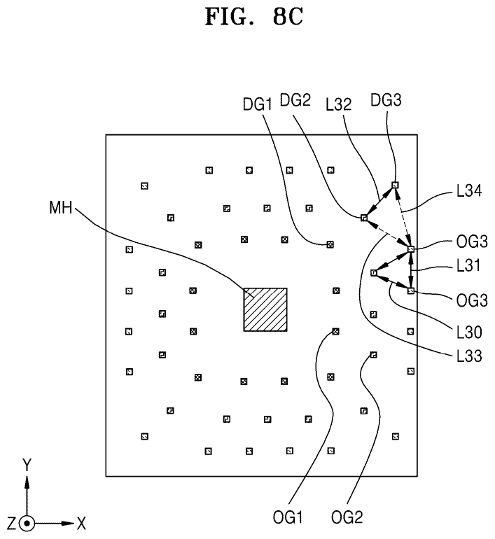

FIGS. 8A, 8B, and 8C are plan views respectively illustrating a sequence of processes of designing a plurality of hole pattern layouts for manufacturing a photomask according to some embodiments. FIGS. 8A, 8B, and 8C respectively illustrate a sequence of processes of designing a hole pattern layout in a quadrangular layout region that is centered around a hole pattern layout corresponding to the main hole pattern MH.

Referring to FIGS. 8A, 8B, and 8C, when a plurality of first hole pattern layouts are designed, to design a plurality of first hole pattern layouts arranged symmetrically with respect to a hole pattern layout corresponding to the main hole pattern MH, a plurality of first grids (that is, OG1 and DG1), a plurality of second grids (that is, OG2 and DG2), and a plurality of third grids (that is, OG3 and DG3) may be sequentially generated in the stated order.

The plurality of first grids (that is, OG1 and DG1) may include a plurality of first orthogonal grids OG1 and a plurality of first diagonal grids DG1. The plurality of second grids (that is, OG2 and DG2) may include a plurality of second orthogonal grids OG2 and a plurality of second diagonal grids DG2. The plurality of third grids (that is, OG3 and DG3) may include a plurality of third orthogonal grids OG3 and a plurality of third diagonal grids DG3.

As shown in FIG. 8A, a distance H between the main hole pattern MH and a first orthogonal grid OG1 may be determined by setting an exposure illumination condition to allow a process window to be maximized. In the plurality of first grids (that is, OG1 and DG1), a distance L11 between the plurality of first orthogonal grids OG1 and a distance L12 between a first orthogonal grid OG1 and a first diagonal grid DG1 may each be set to have a pitch P that is not greater than a diffraction limit in a photolithography process.

As shown in FIG. 8B, the plurality of second grids (that is, OG2 and DG2) may be generated around the plurality of first grids (that is, OG1 and DG1). Here, a distance L20 between the first orthogonal grid OG1 and a second orthogonal grid OG2, a distance L21 between the plurality of second orthogonal grids OG2, and a distance L22 between the first diagonal grid DG1 and a second diagonal grid DG2 may each be set to have a pitch P that is not greater than the diffraction limit in the photolithography process. That is, the distance L20, the distance L21, and the distance L22 may be set to satisfy the conditions of L20=L21=L22=P. In addition, a distance L23 between the first diagonal grid DG1 and the second orthogonal grid OG2 and a distance L24 between the second orthogonal grid OG2 and the second diagonal grid DG2 may each be set to have a value that is at least the pitch P and less than 2P, the pitch P being not greater than the diffraction limit in the photolithography process. That is, the distance L23 and the distance L24 may be set to satisfy the conditions of P≤L23<2P and P≤L24<2P, respectively.

As shown in FIG. 8C, the plurality of third grids (that is, OG3 and DG3) may be generated around the plurality of second grids (that is, OG2 and DG2). Here, a distance L30 between the second orthogonal grid OG2 and a third orthogonal grid OG3, a distance L31 between the plurality of third orthogonal grids OG3, and a distance L32 between a third diagonal grid DG3 and the second diagonal grid DG2 may each be set to have a pitch P that is not greater than the diffraction limit in the photolithography process. That is, the distance L30, the distance L31, and the distance L32 may be set to satisfy the conditions of L30=L31=L32=P. A distance L33 between the second diagonal grid DG2 and the third orthogonal grid OG3 and a distance L34 between the third orthogonal grid OG3 and the third diagonal grid DG3 may each be set to have a value that is at least the pitch P and less than 2P, the pitch P being not greater than the diffraction limit in the photolithography process. That is, the distance L33 and the distance L34 may be set to satisfy the conditions of P≤L33<2P and P≤L34<2P, respectively.

After the processes described with reference to FIGS. 8A to 8C are repeated, a plurality of hole patterns may be formed based on the plurality of first grids (that is, OG1 and DG1), the plurality of second grids (that is, OG2 and DG2), and the plurality of third grids (that is, OG3 and DG3), thereby forming the photomask 100 described with reference to FIGS. 2A and 2B or the photomask 200 described with reference to FIG. 3.

In the process of forming the photomask 100 described with reference to FIGS. 2A and 2B, when the plurality of hole patterns are formed through a plurality of grid processes described with reference to FIGS. 8A to 8C, there may be an interval that is greater than the diffraction limit and located between the non-diffraction SRAF including the plurality of first SRAF hole patterns AH1 and the BARP including the plurality of second SRAF hole patterns AH2. However, because the plurality of first SRAF hole patterns AH1 and the plurality of second SRAF hole patterns AH2 are each arranged with a pitch, which is not greater than the diffraction limit in the photolithography process, to generate non-phase-shifting light, side-lobe printing in a phase-shifting region may be effectively suppressed. Because the non-diffraction SRAF including the plurality of first SRAF hole patterns AH1 are arranged to surround the main hole pattern MH, even when there is a region in which the BARPs including the plurality of second SRAF hole patterns AH2 are asymmetrically arranged, adverse effects due to this may be prevented.

By using an off-axis illumination method in a photolithography process that uses each of the photomasks 100 and 200 according to some embodiments, the effect of preventing side-lobe printing may further improve. In addition, when the off-axis illumination method is used, the effects according to the inventive concepts may be maximized as an off-axis incidence position is farther from the center of the annular illuminator.

According to the inventive concepts, an attenuator of phase-shifting light may be generated by using the plurality of third SRAF hole patterns AH3, which each have a third radius, r3, defined by Inequality 3 described above, as in the photomask 200 shown in FIG. 3. Here, the third radius, r3, of each of the plurality of third SRAF hole patterns AH3 may be less than the first radius, r1, of the first SRAF hole pattern AH1 and the second radius, r2, of the second SRAF hole pattern AH2. The plurality of third SRAF hole patterns AH3 may be inserted between the separation space SPR between the plurality of first SRAF hole patterns AH1 and the plurality of second SRAF hole patterns AH2 to reduce effective reflectivity of a phase-shifting portion while maintaining a phase boundary effect that allows side-lobe printing to be prevented. Therefore, the effect of preventing side-lobe printing may be further ensured.

### Evaluation Example 3

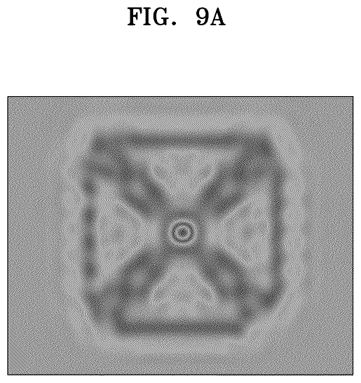

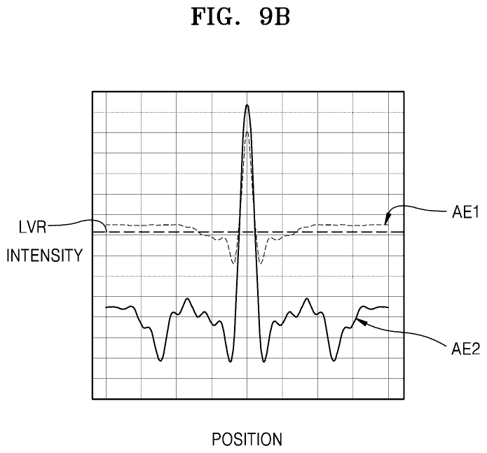

FIG. 9A is an aerial image generated by an exposure process that uses a photomask having the same layout as the photomask 200 shown in FIG. 3. FIG. 9B illustrates an intensity profile AE2 of the aerial image of FIG. 9A. FIG. 9B also illustrates, as a comparison example, an intensity profile AE1 obtained through an exposure process that uses a photomask without the plurality of first SRAF hole patterns AH1 and the plurality of second SRAF hole patterns AH2 around the main hole pattern MH, unlike the photomask 200 shown in FIG. 3. The dashed line LVR in FIG. 9B indicates a threshold reference value at which side-lobe printing occurs.

From the result of FIG. 9B, it may be seen that, by performing an exposure process by using the photomask 200 according to the inventive concepts in a photolithography process, a high-contrast image enough to print the main hole pattern MH may be obtained while the background intensity is low enough to prevent side-lobe printing. Therefore, by using a photomask according to some embodiments, a hole pattern having a high-contrast image may be formed without side-lobe printing.

It will be understood that the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. It will be understood that, although the terms first, second, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

While the inventive concepts have been particularly shown and described with reference to example embodiments thereof, it will be understood that various changes in form and details may be made therein without departing from the scope of the following claims.

What is claimed is:

1. A photomask for a photolithography process, the photomask comprising:
a mask substrate;
a reflective multilayer on the mask substrate; and
a light absorber pattern arranged on the reflective multilayer and having a plurality of hole patterns,
wherein the plurality of hole patterns comprise:
a main hole pattern for transferring a pattern onto a wafer;
a plurality of first sub-resolution assist feature (SRAF) hole patterns arranged at regular intervals to provide a plurality of first honeycomb lattices in a first region, wherein the first region is centered around the main hole pattern, and wherein the plurality of first SRAF hole patterns are arranged with a first pitch that is less than or equal to a diffraction limit in the photolithography process; and
a plurality of second SRAF hole patterns arranged at regular intervals to provide a plurality of second honeycomb lattices in a second region, wherein the plurality of second SRAF hole patterns surround the main hole pattern and the plurality of first SRAF hole patterns, wherein the second region is centered around the main hole pattern and surrounds the first region, and wherein the plurality of second SRAF hole patterns are arranged with a second pitch that is less than or equal to the diffraction limit in the photolithography process.

2. The photomask of claim 1, wherein the plurality of first SRAF hole patterns are respectively arranged one-by-one at positions of vertices of each of the plurality of first honeycomb lattices, and the plurality of second SRAF hole patterns are respectively arranged one-by-one at positions of vertices of each of the plurality of second honeycomb lattices,
wherein ones of the plurality of first honeycomb lattices have a hexagonal shape and regularly overlap each other in a plan view,
wherein ones of the plurality of second honeycomb lattices have a hexagonal shape and regularly overlap each other in the plan view,
and wherein the plurality of first SRAF hole patterns are arranged symmetrically with respect to a straight line extending through the main hole pattern, and the plurality of second SRAF hole patterns are arranged symmetrically with respect to the straight line extending through the main hole pattern.

3. The photomask of claim 1, wherein the plurality of first SRAF hole patterns comprise:
a plurality of first local groups each comprising a first subset of the plurality of first SRAF hole patterns that are arranged to provide ones of the plurality of first honeycomb lattices; and
a plurality of second local groups each comprising a second subset of the plurality of first SRAF hole patterns between adjacent ones of the plurality of first local groups, the second subset of the plurality of first SRAF hole patterns being linearly arranged along a straight line extending in a radial direction away from the main hole pattern.

4. The photomask of claim 1, wherein a first radius, r1, of each of the plurality of first SRAF hole patterns is determined according to Inequality 1:
$$P 1 > r 1 > \sqrt{\frac{1.5 \cdot \sqrt{3} \cdot {( P 1 )}^{2} \cdot ( \sqrt{0.03} + \sqrt{R F} )}{3 \cdot π \cdot ( 1 + \sqrt{R F} )}} \qquad [ Inequality 1 ]$$
wherein, in Inequality 1:
P1 is the first pitch of the plurality of first SRAF hole patterns, and
RF is reflectivity in the light absorber pattern of the photomask.

5. The photomask of claim 1, wherein a second radius, r2, of each of the plurality of second SRAF hole patterns is determined according to Inequality 2:
$$P 2 > r 2 > \sqrt{\frac{1.5 \cdot \sqrt{3} \cdot {( P 2 )}^{2} \cdot ( \sqrt{0.03} + \sqrt{R F} )}{3 \cdot π \cdot ( 1 + \sqrt{R F} )}} \qquad [ Inequality 2 ]$$
wherein, in Inequality 2:
P2 is the second pitch of the plurality of second SRAF hole patterns, and
RF is reflectivity in the light absorber pattern of the photomask.

6. The photomask of claim 1, wherein, in a local region centered around the main hole pattern, a number of the plurality of second SRAF hole patterns is greater than a number of the plurality of first SRAF hole patterns, and
wherein the first pitch is equal to the second pitch.

7. The photomask of claim 1, further comprising a plurality of third SRAF hole patterns between the plurality of first SRAF hole patterns and the plurality of second SRAF hole patterns,
wherein the plurality of third SRAF hole patterns are linearly arranged along a straight line in a separation space between the plurality of first SRAF hole patterns and the plurality of second SRAF hole patterns.

8. The photomask of claim 1, further comprising a plurality of third SRAF hole patterns arranged between the plurality of first SRAF hole patterns and the plurality of second SRAF hole patterns to have a third pitch that is less than or equal to the diffraction limit in the photolithography process,
wherein a third radius, r3, of each of the plurality of third SRAF hole patterns is determined according to Inequality 3:
$$\sqrt{\frac{1.5 \cdot \sqrt{3} \cdot {( P 3 )}^{2} \cdot \sqrt{R F} )}{3 \cdot π \cdot ( 1 + \sqrt{R F} )}} \geq r 3 \qquad [ Inequality 3 ]$$
wherein, in Inequality 3:
P3 is the third pitch of the plurality of third SRAF hole patterns, and
RF is reflectivity in the light absorber pattern of the photomask.

9. The photomask of claim 1, further comprising a plurality of third SRAF hole patterns arranged between the plurality of first SRAF hole patterns and the plurality of second SRAF hole patterns to have a third pitch that is less than or equal to the diffraction limit in the photolithography process,
wherein, in a local region centered around the main hole pattern, a number of the plurality of second SRAF hole patterns is greater than a number of the plurality of first SRAF hole patterns, and a number of the plurality of third SRAF hole patterns is less than the number of the plurality of first SRAF hole patterns.

10. The photomask of claim 1, wherein the photolithography process uses an extreme ultraviolet (EUV) light source as an exposure light source.

11. A photomask for a photolithography process that uses an extreme ultraviolet (EUV) light source, the photomask comprising:
a mask substrate;
a reflective multilayer on the mask substrate; and
a light absorber pattern arranged on the reflective multilayer and having a plurality of hole patterns,
wherein the plurality of hole patterns comprise:
a plurality of main hole patterns for transferring a pattern onto a wafer;
a plurality of first sub-resolution assist feature (SRAF) hole patterns comprising a plurality of first local groups and a plurality of second local groups, wherein the plurality of second local groups are respectively arranged between ones of the plurality of first local groups, wherein a first subset of the plurality of first SRAF hole patterns are included in each of the plurality of first local groups and are arranged at regular intervals to provide a plurality of first honeycomb lattices in a first region, wherein the first region is centered around one of the plurality of main hole patterns, wherein a second subset of the plurality of first SRAF hole patterns are included in each of the plurality of second local groups and are linearly arranged along a straight line extending in a radial direction away from the one of the plurality of main hole patterns, and wherein at least the first subset of the plurality of first SRAF hole patterns are arranged with a first pitch that is less than or equal to a diffraction limit in the photolithography process; and
a plurality of second SRAF hole patterns arranged at regular intervals to provide a plurality of second honeycomb lattices in a second region, wherein the plurality of second SRAF hole patterns surround the plurality of main hole patterns and the plurality of first SRAF hole patterns, wherein the second region is centered around the one of the plurality of main hole patterns and surrounds the first region, and wherein the plurality of second SRAF hole patterns are arranged with a second pitch that is less than or equal to the diffraction limit in the photolithography process.

12. The photomask of claim 11, wherein the first region is a quadrangular region centered around the one of the plurality of main hole patterns,
wherein the first subset of the plurality of first SRAF hole patterns included in each of the plurality of first local groups are arranged in a triangular region between the one of the plurality of main hole patterns and one side of the quadrangular region, and
wherein the second subset of the plurality of first SRAF hole patterns included in each of the plurality of second local groups are linearly arranged along the straight line, and the straight line extends from the one of the plurality of main hole patterns toward a vertex of the quadrangular region.

13. The photomask of claim 11, wherein, in each of the plurality of first local groups in the first region, a first radius, r1, of each of the plurality of first SRAF hole patterns of the first subset is determined according to Inequality 1:
$$P 1 > r 1 > \sqrt{\frac{1.5 \cdot \sqrt{3} \cdot {( P 1 )}^{2} \cdot ( \sqrt{0.03} + \sqrt{R F} )}{3 \cdot π \cdot ( 1 + \sqrt{R F} )}} \qquad [ Inequality 1 ]$$
wherein, in Inequality 1:
P1 is the first pitch of the first subset of the plurality of first SRAF hole patterns, and
RF is reflectivity in the light absorber pattern of the photomask,
wherein, in the second region, a second radius, r2, of each of the plurality of second SRAF hole patterns is determined according to Inequality 2:
$$P 2 > r 2 > \sqrt{\frac{1.5 \cdot \sqrt{3} \cdot {( P 2 )}^{2} \cdot ( \sqrt{0.03} + \sqrt{R F} )}{3 \cdot π \cdot ( 1 + \sqrt{R F} )}} \qquad [ Inequality 2 ]$$
wherein, in Inequality 2:
P2 is the second pitch of the plurality of second SRAF hole patterns, and
RF is the reflectivity in the light absorber pattern of the photomask.

14. The photomask of claim 11, wherein the light absorber pattern comprises a non-pattern region between the plurality of first SRAF hole patterns concentrated in the first region and the plurality of second SRAF hole patterns concentrated in the second region, the non-pattern region having a width that is greater than each of the first pitch and the second pitch.

15. The photomask of claim 11, further comprising a plurality of third SRAF hole patterns arranged between the plurality of first SRAF hole patterns and the plurality of second SRAF hole patterns to have a third pitch that is less than or equal to the diffraction limit in the photolithography process,
wherein the plurality of third SRAF hole patterns are linearly arranged along a straight line, and
wherein a third radius, r3, of each of the plurality of third SRAF hole patterns is determined according to Inequality 3:
$$\sqrt{\frac{1.5 \cdot \sqrt{3} \cdot {( P 3 )}^{2} \cdot \sqrt{R F} )}{3 \cdot π \cdot ( 1 + \sqrt{R F} )}} \geq r 3 \qquad [ Inequality 3 ]$$
wherein, in Inequality 3:
RF is reflectivity in the light absorber pattern of the photomask, and
P3 is the third pitch of the plurality of third SRAF hole patterns.

16. The photomask of claim 15, wherein, in a local region centered around the one of the plurality of main hole patterns, a number of the plurality of second SRAF hole patterns is greater than a number of the plurality of first SRAF hole patterns, and a number of the plurality of third SRAF hole patterns is less than the number of the plurality of first SRAF hole patterns.

17. A method of manufacturing an integrated circuit device, the method comprising:
forming a photoresist film on a substrate; and
performing a photolithography process by exposing the photoresist film to light using a photomask,
wherein the photomask comprises:
a mask substrate;
a reflective multilayer on the mask substrate; and
a light absorber pattern arranged on the reflective multilayer and having a plurality of hole patterns,
wherein the plurality of hole patterns comprise:
a plurality of main hole patterns for transferring a pattern onto a wafer;
a plurality of first sub-resolution assist feature (SRAF) hole patterns comprising a plurality of first local groups and a plurality of second local groups, wherein the plurality of second local groups are respectively arranged between ones of the plurality of first local groups, wherein a first subset of the plurality of first SRAF hole patterns are included in each of the plurality of first local groups and are arranged at regular intervals to provide a plurality of first honeycomb lattices in a first region, wherein the first region is centered around one of the plurality of main hole patterns, wherein a second subset of the plurality of first SRAF hole patterns are included in each of the plurality of second local groups and are linearly arranged along a straight line extending in a radial direction away from the one of the plurality of main hole patterns, and wherein at least the first subset of the plurality of first SRAF hole patterns are arranged with a first pitch that is less than or equal to a diffraction limit in the photolithography process; and
a plurality of second SRAF hole patterns arranged at regular intervals to provide a plurality of second honeycomb lattices in a second region, wherein the plurality of second SRAF hole patterns surround the plurality of main hole patterns and the plurality of first SRAF hole patterns, wherein the second region is centered around the one of the plurality of main hole patterns and surrounds the first region, and wherein the plurality of second SRAF hole patterns are arranged with a second pitch that is less than or equal to the diffraction limit in the photolithography process.

18. The method of claim 17, wherein the performing of the photolithography process comprises using an extreme ultraviolet (EUV) light source.

19. The method of claim 17, wherein the first region is a quadrangular region centered around the one of the plurality of main hole patterns,
wherein the first subset of the plurality of first SRAF hole patterns included in each of the plurality of first local groups are arranged in a triangular region between the one of the plurality of main hole patterns and one side of the quadrangular region, and
wherein the second subset of the plurality of first SRAF hole patterns included in each of the plurality of second local groups are linearly arranged along the straight line, and the straight line extends from the one of the plurality of main hole patterns toward a vertex of the quadrangular region.

20. The method of claim 17, wherein the performing of the photolithography process comprises using an off-axis illumination method.
